(19) United States
(12) Patent Application Publication
(10) Pub. No.: US 2008/0001677 A1
(43) Pub. Date: Jan. 3, 2008

(54) Ring oscillator clock

(76) Inventors: Udi Shaked, Kfar-Yona (IL); Doron Karnibad, Netanya (IL)

Correspondence Address: EMPK & Shiloh, LLP, 116 JOHN ST,, SUITE 1201, NEW YORK, NY, 10038, US

(21) Appl. No.: 11/802,119

(22) Filed: May 21, 2007

Related U.S. Application Data
(60) Provisional application No. 60/802,169, filed on May 22, 2006.
(60) Provisional application No. 60/817,090, filed on Jun. 29, 2006.

(51) Int. Cl. H03K 3/30; G01R 33/00

(52) U.S. Cl. 331/44; 331/57

(57) ABSTRACT

A semiconductor integrated circuit comprising: a ring oscillator that produces periodic pulses; and a controller that uses the pulses as clock pulses to determine time.

### RELATED APPLICATIONS

The present application claims the benefit under 35 U.S.C. 119(e) of U.S. Provisional Application 60/802,169 filed on May 22, 2006 and U.S. Provisional Application 60/817,090 filed on Jun. 9, 2006, the disclosures of which are incorporated herein by reference.

### FIELD

The invention relates to timing circuits suitable for use in semiconductor integrated circuits.

### BACKGROUND

Digital circuitry ubiquitously found in almost all modern day appliances and communication devices will often comprise synchronous and asynchronous circuits. Synchronous circuits require and operate in cadence with, regular, clock pulses having a well defined period and generally relatively high, MHz or many MHz, repetition frequency. Typically, electronic components, such as logic gates and flip-flops, in a synchronous circuit change state to implement a function for which the circuit was designed responsive to a rising or falling edge of each clock pulse, and/or to a relatively small number of clock pulses. A timing circuit usually comprising a piezoelectric crystal coupled to a feedback circuit provides the clock pulses. The crystal is characterized by a relatively precise mechanical resonant frequency that provides the timing circuit with an oscillating electrical signal having an accurately defined and maintained frequency, responsive to which the timing circuit provides clock pulses. Asynchronous circuits on the other hand, do not generally require regular clock pulses to perform their functions and are typically triggered to perform their functions responsive to input signals “as they come” and that are not necessarily periodic.

The crystals comprised in timing circuits, hereinafter also referred to as “crystal clocks”, conventionally used to provide high frequency clock pulses for synchronous circuits consume relatively large amounts of energy and are relatively large on a scale of features and footprints of today's semiconductor integrated circuits (IC). Generally, the resonant crystals used to provide clock pulses for synchronous circuits are too large to be comprised inside the synchronous circuits, are externally housed and are connected to the synchronous circuits via suitable conductors and conducting pads. As modern appliances and communication devices become ever smaller and energy thrifty, the space and energy demands of conventional crystal clocks become increasingly disadvantageous and difficult to provide.

In some IC circuits, energy demands of crystal clocks are mitigated by putting synchronous circuits and their crystal clocks to sleep and awakening them when they are needed. For example, hand-held devices that are capable of receiving digital TV broadcasts are generally configured to process the broadcasts in accordance with a digital video broadcast handheld (DVB-H) standard. According to these standards, TV data is transmitted in periodic bursts of data transmitted at relatively high transmission rates that are separated by idle times during which no data is transmitted. Typically, the data bursts have duration of about one second and the idle times duration of about nine seconds. In order to conserve energy, synchronous digital circuits comprised in the handheld devices that are used to process the TV data and their associated crystal clocks are shut down during the idle times. A relatively low frequency crystal “alarm” clock that is on during burst periods and idle periods is typically used to keep track of the burst periods and idle times and generates signals indicating when the synchronous circuits and their clocks are to be “put to sleep” and to be “awakened”. Similarly, cell phones typically are in a sleep state in which most of their synchronous circuits, associated crystal clocks and functionalities are turned off and are periodically awakened to check for paging signals from base stations.

Whereas the low frequency crystal alarm clocks comprise a resonant crystal, their relatively low frequency resonant crystals and associated circuitry dissipate substantially less energy than the relatively high frequency crystals and associated circuitry comprised in the clocks of the synchronous circuits. Energy savings of as much as 90% may be realized by using low frequency crystal alarm clocks to put synchronous circuits to sleep and to awaken them. However, like the synchronous crystal clocks, the low frequency crystal alarm clocks also generally occupy a relatively large space.

### SUMMARY

An aspect of some embodiments of the invention relates to providing a timing circuit for semiconductor integrated circuits that is relatively small and consumes a relatively small amount of energy.

According to an aspect of an embodiment of the invention, the timing circuit comprises a ring oscillator circuit that provides periodic pulses at an output of the circuit that are used to determine time and/or to time circuit functions of an, optionally, semiconductor integrated circuit.

An aspect of some embodiments of the invention relates to calibrating the frequency and/or period of output pulses of a ring oscillator and using the calibrated frequency and/or period of the ring oscillator pulses to measure time and/or to time circuit functions.

Ring oscillator circuits are relatively simple circuits that comprise a daisy chain of an odd number of inverters, or an odd number of inverter and delay element pairs, for which the output of the last inverter is used as an input to the first inverter. Because of the self-referent (the output being fed into the input) configuration, the output of the last inverter oscillates (as do the outputs of all the inverters) with a period substantially equal to the sum of the propagation delays of all of the inverters. Semiconductor ring oscillators occupy substantially less space and dissipate substantially less energy than crystal oscillators and are less expensive than crystal oscillators.

By way of example, a resonant crystal oscillator and associated capacitors comprised in a 32 kHz crystal clock typically have a combined footprint of about 10 mm² and the clock typically draws a current of about 500 μA (microampere). In quantity, the resonant crystal usually costs between about US $0.20 to about US $0.32. On the other hand, a ring oscillator comprising between about 2,000 to 3,000 inverters produced using an IC (integrated circuit) fabrication process having a feature size of about 0.13 μm (micrometers) typically has a footprint of about 0.016 mm² and draws a current less than about 100 μA. For a same voltage, the ring oscillator therefore uses less than about one fifth the power used by the crystal clock. A ring oscillator can generally be produced as part of an IC circuit using a same fabrication process that is used to produce the circuit at a cost that is negligible compared to the cost of a resonant crystal used in a crystal clock.

However, oscillation frequencies of semiconductor ring oscillators are highly variable and are dependent on voltage and temperature at which the oscillators operate and upon the semiconductor fabrication process used in manufacture of the oscillators. As a result, whereas ring oscillators are often used to determine characteristics of a semiconductor manufacturing process, they are generally not considered useable for providing clock signals for determining time and/or to time functions of digital circuits.

The inventors have noted however, that whereas the oscillation frequency of a given ring oscillator is process, voltage and temperature dependent, generally the frequency is relatively stable for relatively extended periods having duration of many clock cycles of a typical crystal clock used in a synchronous circuit. For such extended periods, a ring oscillator may be used, in accordance with an embodiment of the invention, to determine time and/or time functions of IC circuits.

In accordance with an embodiment of the invention, the frequency and/or period of pulses provided by the ring oscillator is calibrated by measuring the frequency and/or period using a clock, hereinafter a “calibration clock”, that provides clock pulses having a relatively precise and accurately known frequency. For example, a frequency of a ring oscillator in accordance with an embodiment of the invention may be determined by comparing how many ring oscillator pulses occur during a period in which a known number of pulses from the calibration clock occur. The calibrated output pulses of the ring oscillator are used to determine time and/or to time circuit functions of an, optionally, integrated semiconductor circuit. Optionally, the ring oscillator pulses are periodically calibrated.

Optionally, the calibration clock is a crystal clock having a frequency that is relatively high compared to a frequency at which the ring oscillator is expected to operate. Optionally, the crystal clock is a clock used to synchronize circuit elements of a synchronous circuit. In some embodiments of the invention, the ring oscillator is used to determine times at which synchronous circuits are put to sleep and awakened. Optionally, the ring oscillator is used to determine times at which the crystal clock that is used to calibrate the ring oscillator, and the synchronous circuit timed by the clock, are put to sleep and awakened.

In some embodiments of the invention, the ring oscillator and the crystal clock are comprised in a telecommunication handset, such as a DVB-H receiver or a cell phone, and is used to determine sleep and awakening times for synchronous circuits comprised in the handset.

There is therefore provided in accordance with an embodiment of the invention, a method of measuring time comprising: fabricating a semiconductor ring oscillator that produces periodic pulses; and using the pulses as clock pulses to determine time. Optionally, the method comprises periodically calibrating the ring oscillator pulses responsive to clock pulses characterized by a repetition frequency greater than a repetition frequency of the ring oscillator pulses.

Optionally, the calibration clock pulses are provided by a crystal clock. Optionally, the crystal clock comprises semiconductor circuitry. Optionally, the ring oscillator and the semiconductor circuitry of the crystal clock are comprised in a same semiconductor circuit or portions of a same semiconductor circuit.

In some embodiments of the invention, the method comprises controlling the clock pulses used to calibrate the ring oscillator pulses responsive to the ring oscillator pulses. Optionally, controlling the clock pulses used to calibrate the ring oscillator pulses comprises turning off the pulses responsive to time determined using the ring oscillator pulses. Alternatively or additionally, controlling the clock pulses used to calibrate the ring oscillator pulses optionally comprises turning on the pulses responsive to time determined using the ring oscillator pulses.

There is further provided in accordance with an embodiment of the invention, a method of controlling a function of a semiconductor integrated circuit, the method comprising: measuring time according to an embodiment of the invention; and controlling a function of the semiconductor integrated circuit responsive to the measured time. Optionally, controlling a function of the semiconductor integrated circuit comprises putting at least a portion of the semiconductor integrated circuit into a sleep mode responsive to the measured time. Optionally, the at least a portion of the semiconductor integrated circuitry comprises a timing circuit. Optionally, the timing circuit comprises a resonant crystal.

In some embodiments of the invention, controlling a function of the semiconductor integrated circuit comprises awakening at least a portion of the semiconductor integrated circuit from a sleep mode responsive to the measured time. Optionally, the at least a portion of the semiconductor integrated circuitry comprises a timing circuit. Optionally, the timing circuit comprises a resonant crystal.

In some embodiments of the invention, the semiconductor integrated circuit is comprised in a cell phone. In some embodiments of the invention, the semiconductor integrated circuit is comprised in a receiver adapted to receive TV signals configured responsive to a DVBH standard.

There is further provided in accordance with an embodiment of the invention, an semiconductor integrated circuit comprising: a ring oscillator that produces periodic pulses; and a controller that uses the pulses as clock pulses to determine time. Optionally, the semiconductor integrated circuit and comprises a crystal clock that provides clock pulses. Optionally, the semiconductor integrated circuit and comprises a calibration circuit that uses clock pulses provided by the crystal clock to calibrate the periodic pulses provided by the ring oscillator. Additionally or alternatively, the controller optionally controls the crystal clock to enter a sleep mode or awake from a sleep mode responsive to the determined time.

In some embodiments of the invention, the semiconductor integrated circuit is comprised in a cell phone. In some embodiments of the invention, the semiconductor integrated circuit is comprised in a receiver adapted to receive TV signals configured responsive to a DVBH standard.

### BRIEF DESCRIPTION OF FIGURES

Non-limiting examples of embodiments of the invention are described below with reference to figures attached hereto and listed following this paragraph. Identical structures, elements or parts that appear in more than one figure are generally labeled with a same numeral in all the figures in which they appear. Dimensions of components and features shown in the figures are chosen for convenience and clarity of presentation and are not necessarily shown to scale.

FIG. 1 shows a schematic block diagram of a portion of a cell phone circuit comprising a crystal clock in accordance with prior art;

FIG. 2A shows a schematic diagram of a ring oscillator, in accordance with prior art;

FIG. 2B shows a schematic block diagram of a portion of a cell phone circuit comprising a ring oscillator, in accordance with an embodiment of the invention;

FIG. 3A shows a schematic diagram of a calibration circuit for determining the period of the ring oscillator % shown in FIG. 2B, in accordance with an embodiment of the invention;

FIG. 3B schematically shows signal waveforms associated with operation of the calibration circuit shown in FIG. 3A; and

FIG. 4 schematically shows data bursts used to transmit TV data in accordance with a DVB-H standard.

### DETAILED DESCRIPTION

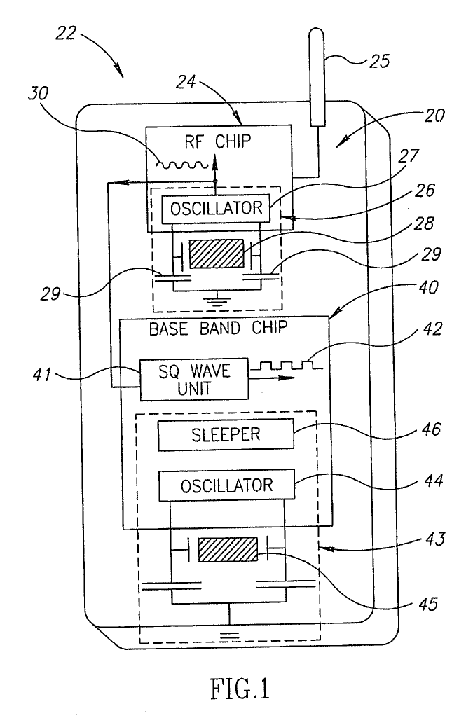

FIG. 1 shows a very schematic block diagram of a portion of a circuit 20 comprised in a cell phone 22, in accordance with prior art. Circuit 20 comprises a radio frequency (“RF”) transceiver chip 24 (RF chip 24) coupled to an antenna 25 for transmitting and receiving cell phone telephone signals and a baseband chip 40 for demodulating and processing the signals transceived by RF chip 24.

RF chip 24 usually comprises a crystal clock 26, schematically indicated by a dashed border, having a high frequency oscillator 27 located inside the chip which is connected to a relatively high frequency resonant crystal 28 and associated capacitors 29 located outside the chip. Crystal 28 conventionally has a resonant frequency of 26 MHz and crystal clock 26 generates a sinusoidal clock signal 30 at the resonant frequency which signal is generally used by circuitry in the RF chip. RF chip 24 also transfers signal 30 to baseband chip 40. The baseband chip comprises a local clock generation unit 41, which converts high frequency sinusoidal signal 30 into a square waveform signal 42 that is used by synchronous circuit elements (not shown) in the cell phone for clocking.

Cell phone 22 optionally has an additional relatively low frequency clock 43 comprising an oscillator 44 coupled to a relatively low frequency resonant crystal 45 for generating a relatively low frequency clock signal for use in controlling sleep periods of cell phone 22. Optionally, crystal 45 has a resonant frequency equal to 32.768 KHz. Optionally oscillator 44 transmits the low frequency clock signal that it generates to a sleeper circuit 46. Sleeper circuit 46 uses the received clock signals to determine when to shut down, i.e put to sleep, and when to awaken high frequency clock 26, high frequency crystal 28 and synchronous circuits (not shown) clocked responsive to clock signals from the high frequency crystal clock.

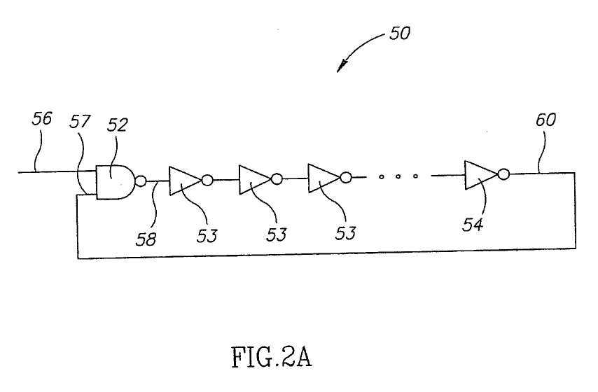

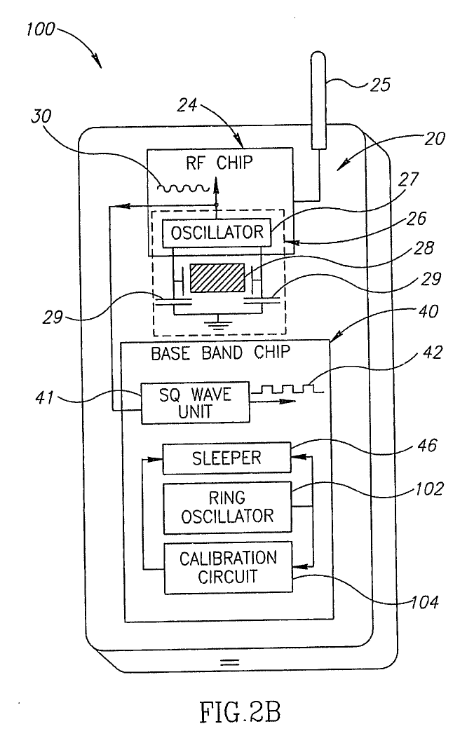

FIG. 2A schematically shows a ring oscillator 50, in accordance with prior art. Ring oscillator 50 optionally comprises a NAND logic gate 52, a plurality of intermediate inverters 53 and a last “output” inverter 54 connected in a daisy chain. The NAND gate has control and feedback gate inputs 56 and 57 respectively, and an output 58. An output 60 of last inverter 54 functions as an output of ring oscillator 50. The NAND logic gate operates as an inverter, which is selectively controllable to start and stop oscillation of a logic level voltage at output 60 of the oscillator by controlling voltage at control input 56. The total number of inverters, including NAND gate 52 operating as an inverter, is odd.

If logic level of control input is set to 0, NAND gate output is 0 and does not change for any value of logic level at feedback input 57 and ring oscillator 50 assumes a stable state with output 60 of the ring oscillator not oscillating. To initiate oscillation, gate input 56 is set to a logic level “1”. For any initial logic level of feedback input 57, a logic level opposite to that at feedback input 57 appears at output 58 of NAND gate 52 and propagates through the chain of inverters 53 and last inverter 54, reversing its logic level at the output of each inverter. Because the total number of inverters is odd, a logic level opposite to that at feedback input 57 appears at output 60 of ring oscillator 50. The logic level at output 60 propagates back to the feedback input causing the logic level of the feedback input to reverse and restarting the cycle with opposite polarity. As a result, the logic level of output 60 oscillates, generating “clock pulses” at the output with a switching frequency that is substantially equal to an inverse of a sum of the propagation delays of all of the inverters. The clock pulses at the output are referred to below in the text as pulses “ro_clk”.

The propagation delays and thereby the switching frequency of a ring oscillator such as ring oscillator 50, are functions of an operating voltage of the ring oscillator, ambient temperature of the oscillator environment and characteristics of the oscillator's fabrication process. For a given chip, following production, effects of the fabrication process on the ring oscillator frequency do not generally change with time and do not as a result, generate changes in the frequency of the oscillator. And for periods, hereinafter referred to as “stable periods”, that are relatively short with respect to periods over which operating voltage and/or ambient temperature are liable to change, the oscillator generally exhibits a relatively stable oscillation frequency. For periods shorter than the stable period, the oscillator can be used, in accordance with an embodiment of the invention, to provide clock pulses useable relatively accurately to determine time and/or time functions of IC circuits.

In accordance with some embodiments of the invention, a calibration circuit is used to determine the oscillator frequency of a ring oscillator and provide a calibrated ring oscillator frequency that is useable to determine time and/or time functions of an IC circuit. In an embodiment of the invention, the calibration circuit is controlled to periodically calibrate the oscillator frequency. Optionally, a time lapse between times at which the calibration circuit calibrates the ring oscillator is less than the stable period of the oscillator. In some embodiments of the invention, the calibration circuit and the ring oscillator are comprised in a same circuit. Optionally, the calibration circuit and ring oscillator are comprised in an IC circuit for which the ring oscillator provides timing functions. In some embodiments of the invention, a ring oscillator and calibration circuit are used in place of a relatively low frequency crystal clock to determine when to put a synchronous circuit and its associated high frequency clock into a sleep mode and when to awaken the clock and synchronous circuit.

By way of example, FIG. 2B schematically shows a cell phone 100 similar to cell phone 22 shown in FIG. 1 but having a ring oscillator 102 and calibration circuit 104, in accordance with an embodiment of the invention. Ring oscillator 102 and calibration circuit 104 replace low frequency clock 43 comprised in cell phone 22. Except for replacement of low frequency clock 43 by ring oscillator 102 and calibration circuit 104 cell phone 100 optionally comprises the same components as cell phone 22.

In accordance with an embodiment of the invention, ring oscillator 102 generates clock signals that it transmits to sleeper circuit 46. The clock signals are also transmitted to calibration circuit 104, which calibrates the clock signals by providing a relatively accurate measurement of the frequency and/or period of the clock signals. Optionally, calibration circuit 104 is controlled by a suitable controller (not shown) in cell phone 100 to periodically calibrate the clock signals. Optionally, a time lapse between times at which the calibration circuit calibrates the ring oscillator is less than the stable period of the oscillator. Optionally, the time lapse is a predetermined time lapse. The calibration circuit transmits the frequency and/or period measurement to sleeper circuit 46. The sleeper circuit uses the clock signals and the frequency and/or period measurements to determine when to put to sleep high frequency clock 26 and circuits for which it provides clock signals and when to awaken the high frequency clock and circuits.

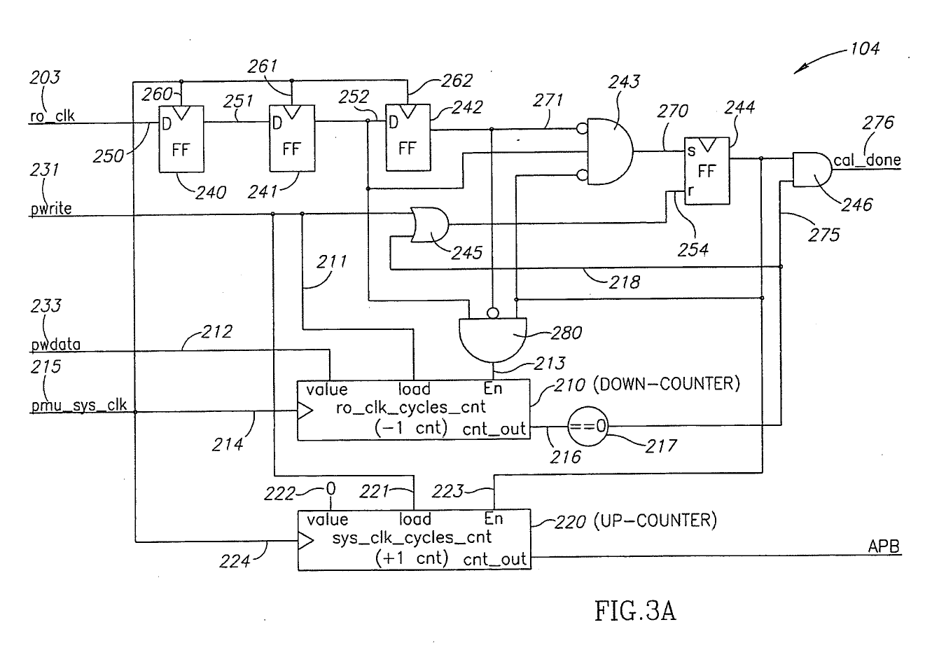

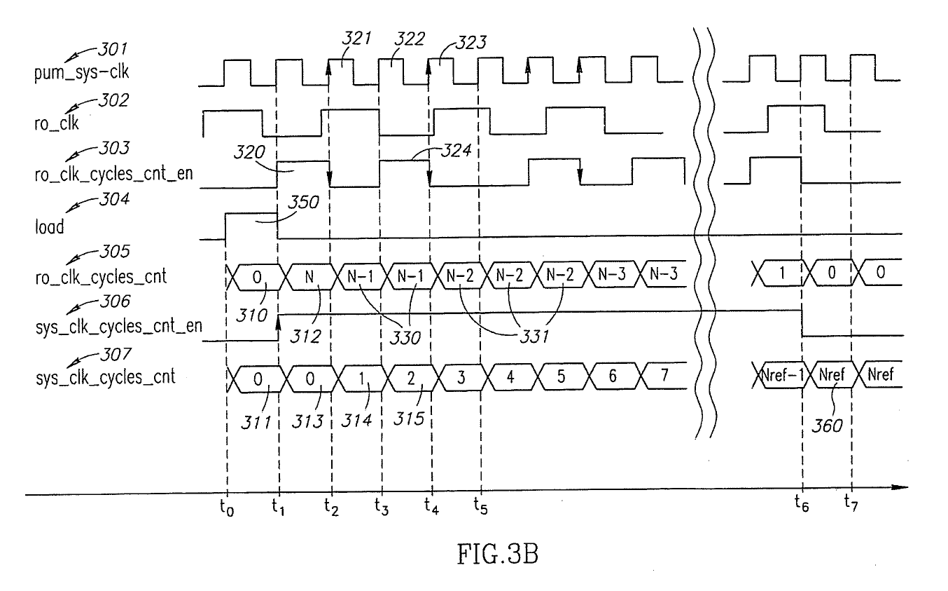

FIG. 3A shows a schematic diagram of calibration circuit 104 for determining the period of ring oscillator 102 shown in FIG. 2B, in accordance with an embodiment of the invention.

The ring oscillator's frequency may be measured by using a timer to generate a measurement temporal window (TW), and a counter, to count a given predetermined number “N_{RO}” of ring oscillator output clock pulses “ro_clk” 203 corresponding to the measurement TW. Accordingly, calibration circuit 104 may include, among other things, two counters: down-counter 210 and up-counter 220. The way the timer and counter are utilized is described below.

Down-counter 210 may count a predetermined number N_{RO} of clock pulses ro_clk of the ring oscillator, and up-counter 220 may be utilized as a counter to generate a precise measurement of the temporal window TW during which N_{RO} is counted. In general, each time ro_clk 203 rises, a pulse is generated by a logical AND gate 243, which triggers (shown at 270) the ‘S’ (SET) input of SR flip-flop 244, and another pulse (shown at 213) is generated by a logical AND gate 280, which is applied to the enable input “En” of down-counter 210. Both counters (down-counter 210 and up-counter 220) “count” using “system” clock signals referred to as pmu_sys_clk signals (shown at 215) as a common clock signal. Up-counter 220 counts pmu_sys_clk cycles as long as the count value of down-counter 210 has not reached zero. Optionally, pmu_sys_clk signals are provided by high frequency crystal clock 26. Down-counter 210 is optionally enabled using rising edges of the ro_clk pulses shown at 203. When the predetermined value N_{RO} of ro_clk pulses is completely counted by down-counter 210, up-counter 220 stops counting. The system clock signals pmu_sys_clk counted by up-counter 220 represents a number “N_{REF}” of system clock signals that was required to count the predetermined number N_{RO} of ro_clk 203 pulses provided by ring oscillator 102 (FIG. 2B).

Measuring the frequency of ring oscillator 102 optionally begins by simultaneously resetting and activating down-counter 210 and up-counter 220. By “resetting and activating down-counter 210” is meant providing (shown at 211) a “pwrite” control signal (shown at 231) to a ‘Load’ input of down-counter 210, entering, or programming (shown at 212) the predetermined number N_{RO} (shown at 233) to a “Value” input of down-counter 210 and providing an enabling control signal “En”, shown at 213 for activating down-counter 210 to enable down-counter 210 to count down to zero from N_{RO}. Likewise, by “resetting and activating up-counter 220” is meant providing a “Load” control signal (shown at 221) to up-counter 220, initializing a ‘Value’ input of up-counter 220 with zero (shown at 222) and providing an enabling control signal “En”, (shown at 223) to up-counter 220.

Once down-counter 210 is enabled, its programmed value N_{RO} is decremented by one each time down-counter 210 is clocked (shown at 214) by a ring oscillator output clock pulse ro_clk 203 via AND gate 280. Once up-counter 220 is enabled (En=1 at 223), its content is incremented by one each time up-counter 220 is clocked (shown at 224) by the reference system clock signal pmu_sys_clk (shown at 215) and as long as the count value of down-counter 210 has not reached zero and it is enabled (En=1). A current value of the down counter (‘cnt_out’, shown at 216) is forwarded to a comparator 217 programmed having a reference value equal to zero. When the count value of down-counter 210 reaches zero, comparator 217 outputs a termination signal (shown at 218 and 275) to indicate that down-counter 210 has completed (and therefore stopped) the counting of the programmed number N_{RO}. The termination signal 275 is forwarded from down-counter 210 through comparator 217 to a logical AND gateway 246, to generate a ‘calibration-done’ signal (‘cal_done’, shown at 276). The termination signal 218 is also forwarded to a logical OR gate 245, which causes OR gate 245 to forward to an RS flip-flop 244 a reset signal (shown at 254), causing, thereby, down-counter 210 and up-counter 220 to be disabled. This way, up-counter 220 counts a number of reference cycles that establishes the measurement temporal window TW during which the number N_{RO} of ro_clk 203 pulses generated by ring oscillator 102 is counted by down-counter 210.

Since pmu_sys_clk pulses provided by high frequency crystal clock 26 have a known precise frequency and period T_{REF} a controller (not shown) in cell phone 100 may calculate the measurement temporal window TW duration as a value equal to the number N_{REF} reached by up-counter 220 multiplied by T_{REF} i.e TW=N_{REF}×T_{REF}. For example, if N_{REF}=10,000 (cycles) and T_{REF}=0.1 msec, then TW equals 1 second (TW=N_{REF}×T_{REF}=10,000×0.1×10⁻³=1 second).

An average period T_{RO} of ring oscillator clock pulses ro_clk 203 may be obtained using an expression:
T_{RO}=TW/N_{RO}=(N_{REF}×T_{REF})/N_{RO} (1)

As explained above, high frequency clock generators consume a considerable amount of power. However, after calculation of T_{RO}, high frequency clock 26 in cell phone 100 may be put to sleep to conserve power while ring oscillator 102 keeps track of timing aspects of circuits in cell phone 100, in accordance with an embodiment of the invention. Since ring oscillator 102 is expected to keep working at substantially a same known frequency provided by calibration circuit 104 for a time equal to a stable period following a last calibration of ring oscillator 102, a number “N_{TASK}” of ring oscillator clock pulses required to measure a duration T_{TASK} for performance of a given task may be relatively easily calculated. For example, if a task to be performed by a circuit in cell phone 100 is expected to have a duration T_{TASK} seconds, then a controller in cell phone 100 can calculate a corresponding number of ring oscillator cycles N_{TASK} by using an expression:
N_{TASK}=T_{TASK}/T_{RO} (2)

Because of the much higher frequency of high frequency crystal clock 26 relative to the frequency of ring oscillator 102 (which is used to replace low frequency clock 43) the measurement of the ring oscillator frequency and/or period is relatively accurate.

According to some embodiments the measurement of frequency and/or period of ring oscillator 102 may be determined, defined, adjusted, or adapted, according to an actual need, requirement or application. That is, as a general rule, the higher the required precision, the larger the number, N_{RO}, of ro_clk pulses 203 (FIG. 3A) that are to be counted by down-counter 210, and the longer the measurement temporal window (TW), which implies that more system clock pulses pmu_sys_clk provided by high frequency crystal clock 26 have to be counted. Since a relationship between precision of the ring oscillator frequency measurement and a total measurement time TW is roughly linear (the higher the precision the more time it takes to complete a measurement cycle), a compromise, or tradeoff, may be exercised.

In determining TW in terms of system clock pulses pmu_sys_clk an acceptable inaccuracy may be defined, as follows. First, an acceptable inaccuracy I (in PPM) in measuring a time duration, such as for example a sleep period, may be defined, for example by allowing an error of ±100 microsecond (μsec.) per 1 second (i.e. 100 PPM) of the sleep period. In terms of clock pulses pmu_sys_clk, if a value N_{RO}=10⁶ is initially programmed to down-counter 210 (ro_clk_cycles_cnt), an imprecision of ±1 PPM may be obtained. In order to get I=100 (in PPM) there is a need to program a minimal value of 10,000 to down-counter 210. While down-counter 210 counts 10,000 ring oscillator clock pulses—ro_clk (from 10,000 to zero), up-counter 220 may reach, by that time, a maximal value that can be calculated by using an expression:
N_{REF}=(1/I)×10⁶×N_{REF}/F_{RO} (3)

Since the value of F_{RO} is unknown, a lowest possible frequency for F_{RO} (in a slow fabrication process with relatively low voltage and relatively high temperature) may be used in expression (3) using a lowest F_{RO} provides an upper bound on N_{REF}, and a time length required for determining frequency and/or period of clock pulses ro_clk of ring oscillator 102 and calibrating thereby the ring oscillator.

### EXAMPLE-1

Assuming that the frequency of system clock pulses pmu_sys_clk is 40 MHz, an inaccuracy of 100 PPM may be considered acceptable and the ring oscillator frequency F_{RO} may be between 5 MHz and 15 MHz. N_{REF} may be found by using expression (3), as follows:

$${N}_{REF} = \frac{1 / 100 \times {10}^{6} \times 40 \times {10}^{6}}{5 \times {10}^{6}} = 80 \times {10}^{3}$$

Therefore, measuring the frequency (within an inaccuracy of 100 PPM) of ring oscillator 102 will require about 2 msec (milliseconds), because the period of each one of the 80,000 clock pulses pmu_sys_clk is about 0.025 μsec.
(T_{REF}=1/40×10⁶=0.025 μsec.).

### EXAMPLE-2

If F_{REF} and F_{RO} are the same as in Example-1 (40 MHz and 5 MHz to 15 MHz, respectively), but now that an inaccuracy of 10 PPM, is desired, N_{REF} becomes,

$${N}_{REF} = \frac{1 / 10 \times {10}^{6} \times 40 \times {10}^{6}}{5 \times {10}^{6}} = 800 \times {10}^{3} ,$$

and, measuring the frequency of the ring oscillator requires about 20 msec.

Logic devices 240, 241 and 242 are D-type flip-flops and logic device 244 is an RS-type flip-flop. In electronics and digital circuits, a flip-flop is a pulsed (clocked) digital circuit capable of serving as a one-bit memory whose non-inverting output (Q) logic value may be either ‘0’ or ‘1’. A flip-flop typically includes zero, one or two input signals; a clock (a strobe) signal; and an output signal, though many commercial flip-flops additionally provide the complement (inverted output Q̅) of the output signal. Some flip-flops also include a clear input signal, which resets the current output. Flip-flops are typically implemented as integrated circuit (IC) chips. A D-type (delay) flip-flop takes one input (D-input), which it conveys to the output when the clock input is strobed by a clock or strobe signal. Regardless of the current value of the output, it will assume a value 1 if D=1 when the flip-flop is strobed, or a value 0 if D=0 and the flip-flop is strobed.

FIG. 3B, schematically shows several signal waveforms that are associated with the operation of calibration circuit 104 shown in FIG. 3A.

Signal 301 represents high frequency clock pulses, pmu_sys clk, and is the system clock. Signal 302 represents oscillator clock pulses ro_clk provided by ring oscillator 102 (FIG. 2B) whose repetition frequency f_{RO} is to be determined by calibration circuit 104, in accordance with an embodiment of the invention. Signal 303 (ro_clk_cycles_cnt_en) is the enable signal (shown at 213 in FIG. 3A) input to down-counter 210. Signal 304 (“load”) is the load signal. Signal 305 (ro_clk_cycles_cnt) is the count value of down-counter 210. Signal 306 (sys_clk_cycles_cnt_en) is the enable signal (shown at 223 in FIG. 3A) input to up-counter 220. Signal 307 (sys_clk_cycles_cnt) is the count number of the up-counter 220.

Between time instants tₒ and t₁, the values of down-counter 210 and up-counter 220 are zero (shown at 310 and 311, respectively). However, “load” signal 350 corresponding to pwrite signal 231 in FIG. 3A, causes down-counter 210 and up-counter 220 to be initially loaded (programmed) with N_{RO} (shown at 312) and zero (shown at 313) respectively. At time t₁ signal 306 (sys_clk_cycles_cnt_en) switches from logic level 0 to logic level 1, and, as long as it remains at logic level 1, each clock of signal 301 (pmu_sys_clk) increments the count value, sys_clk_cycles_cnt, of up-counter 220.

For example, clock 321 increments the count value of up-counter 220 from zero (shown at 313) to 1 (shown at 314). Likewise, clock 322 increments the count value of up-counter 220 from 1 (shown at 314) to 2 (shown at 315), and so on. As described above, the count value of up-counter 220 increments as long as signal 306 (sys_clk_cycles_cnt_en) remains at logic level 1, and signal 306 (sys_clk_cycles_cnt_en) remains at logic level 1 so long as the count-value of down-counter 210 has not reached zero.

The number, ro_clk_cycles_cnt (signal 305), of ro_clk pulses, is decremented each time ro_clk_cycles_cnt_en (signal 303) is at logic level 1 and, at the same time, a system clock pmu_sys_clk, signal 301) exists. For example, down-counter 210 enable pulse 320 and system clock 321 cause the count value of down counter 210 to be decremented from the initially programmed value N_{RO}, shown for convenience as “N” at 312 in FIG. 3B, to ‘N−1’ (shown at 330). Likewise, down-counter 210 enable pulse 324 and system clock 323 cause the count value of down counter 210 to be decremented from ‘N−1’ (shown at 330) to ‘N−2’ (shown at 331), and so on. At a time 16 the count value (ro_clk_cycles_count, signal 305) of down-counter 210 is decremented from 1 to 0. The reduction to 0 of ro_clk_cycles_count causes enable signal 306, sys_clk_cnt_en, of up-counter 220 to switch from logic level 1 to logic level 0 and stop the count at up-counter 220 at a last reached count N_{REF} shown at 360.

Whereas the above description refers to use of a ring oscillator in a cell phone, methods and devices in accordance with embodiments of the invention are not limited to use in cell phone. The methods and devices may be used in any circuit or system for which stable periods of a ring oscillator are sufficiently long to enable performance of advantageous time measurements. For example, a ring oscillator may be used in hand communicators configured to receive TV signals in accordance with any of various DVB-H standards.

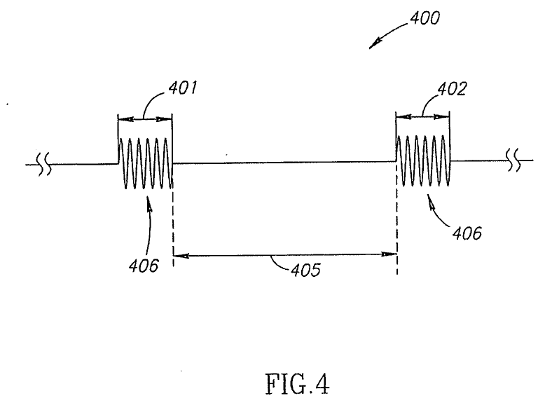

FIG. 4 schematically shows an exemplary DVB-H TV signal 400 comprising bursts 401 and 402 of TV data encoded in an RF carrier wave 406 and separated by a silent period 405. Typically, burst 401 and 402 may have a duration of about 1 second and silent period 405 a duration of about 10 seconds.

As part of the DVB-H standard, each data burst 401 and 402 that is received at a DVB-H receiver notifies the receiver when a next data burst is due. For example, data burst 401 may include data that indicates to the receiver that the next data burst (data burst 402, in this example) is due after following silent period 405. The receiver may utilize a ring oscillator, in accordance with an embodiment of the invention, such as a ring oscillator similar to ring oscillator 50 or 102 (FIG. 2A or 2B respectively) to measure time lapse from a time at which data burst 401 ends while a system, high frequency optionally crystal clock in the receiver is asleep. According to the DVB-H standard, the system clock and associated processing circuits in the receiver must be awake to handle data processing during burst reception. Therefore, as the time lapse measured using pulses provided by the ring oscillator approaches the duration of silent period 405 a controller in the receiver, responsive to the ring oscillator measured time lapse, awakens the system clock and associated processing circuits.

Optionally, during times at which the system crystal clock is awake, clock pulses provided by the system clock are used by a calibration circuit, for example a calibration circuit similar to calibration circuit 104 (FIG. 3A), to calibrate clock pulses provided by the ring oscillator to a desired accuracy as described above. Optionally the oscillator is calibrated during data burst periods, such as data burst periods 401 and 402. For example, the ring oscillator may be calibrated during data burst 401. After being calibrated during burst 401 the ring oscillator pulses may be utilized by the receiver to relatively accurately measure elapsed time during silent period 405, which immediately follows data burst 401.

In the description and claims of the present application, each of the verbs, “comprise” “include” and “have”, and conjugates thereof, are used to indicate that the object or objects of the verb are not necessarily an exhaustive listing of members, components, elements or parts of the subject or subjects of the verb.

The invention has been described with reference to embodiments thereof that are provided by way of example and are not intended to limit the scope of the invention. The described embodiments comprise different features, not all of which are required in all embodiments of the invention. Some embodiments of the invention utilize only some of the features or possible combinations of the features. Variations of embodiments of the described invention and embodiments of the invention comprising different combinations of features than those noted in the described embodiments will occur to persons of the art. The scope of the invention is limited only by the following claims.

1. A method of measuring time comprising:
fabricating a semiconductor ring oscillator that produces periodic pulses; and
using the pulses as clock pulses to determine time.

2. A method according to claim 1 and comprising periodically calibrating the ring oscillator pulses responsive to clock pulses characterized by a repetition frequency greater than a repetition frequency of the ring oscillator pulses.

3. A method according to claim 2 wherein the calibration clock pulses are provided by a crystal clock.

4. A method according to claim 3 wherein the crystal clock comprises semiconductor circuitry.

5. A method according to claim 4 wherein the ring oscillator and the semiconductor circuitry of the crystal clock are comprised in a same semiconductor circuit or portions of a same semiconductor circuit.

6. A method according to claim 2 and controlling the clock pulses used to calibrate the ring oscillator pulses responsive to the ring oscillator pulses.

7. A method according to claim 6 wherein controlling the clock pulses used to calibrate the ring oscillator pulses comprises turning off the pulses responsive to time determined using the ring oscillator pulses.

8. A method according to claim 6 wherein controlling the clock pulses used to calibrate the ring oscillator pulses comprises turning on the pulses responsive to time determined using the ring oscillator pulses.

9. A method of controlling a function of a semiconductor integrated circuit, the method comprising:
measuring time according to any of claims 1-8; and
controlling a function of the semiconductor integrated circuit responsive to the measured time.

10. A method according to claim 9 wherein controlling a function of the semiconductor integrated circuit comprises putting at least a portion of the semiconductor circuit into a sleep mode responsive to the measured time.

11. A method according to claim 10 wherein the at least a portion of the semiconductor integrated circuitry comprises a timing circuit.

12. A method according to claim 11 wherein the timing circuit comprises a resonant crystal

13. A method according to claim 9 wherein controlling a function of the semiconductor integrated circuit comprises awakening at least a portion of the semiconductor circuit from a sleep mode responsive to the measured time.

14. A method according to claim 13 wherein the at least a portion of the semiconductor integrated circuit comprises a timing circuit.

15. A method according to claim 14 wherein the timing circuit comprises a resonant crystal.

16. A method according to claim 9 wherein the semiconductor integrated circuit is comprised in a cell phone.

17. A method according to claim 9 wherein the semiconductor integrated circuit is comprised in a receiver adapted to receive TV signal configured responsive to a DVBH standard.

18. A semiconductor integrated circuit comprising:
a ring oscillator that produces periodic pulses; and
a controller that uses the pulses as clock pulses to determine time.

19. A semiconductor integrated circuit according to claim 18 and comprising a crystal clock that provides clock pulses.

20. A semiconductor integrated circuit according to claim 19 and comprising a calibration circuit that uses clock pulses provided by the crystal clock to calibrate the periodic pulses provided by the ring oscillator.

20. An semiconductor integrated circuit according to claim 19 wherein the controller controls the crystal clock to enter a sleep mode or awake from a sleep mode responsive to the determined time.

21. A semiconductor integrated circuit according to claim 20 wherein the integrated semiconductor circuit is comprised in a cell phone.

22. A semiconductor integrated circuit according to claim 20 wherein the integrated circuit is comprised in a receiver adapted to receive TV signal configured responsive to a DVBH standard.
